(19) United States
(12) Patent Application Publication
(10) Pub. No.: US 2015/0214172 A1
(43) Pub. Date: Jul. 30, 2015

(54) MEMORY AND LAYOUT METHOD OF MEMORY BALL PADS

(71) Applicant: EOREX CORPORATION, HSINCHU COUNTY (TW)

(72) Inventors: CHENG-LUNG LIN, HSINCHU COUNTY (TW); WAN-TUNG LIANG, HSINCHU COUNTY (TW); CHENG-WEI HSU, HSINCHU COUNTY (TW)

(73) Assignee: EOREX CORPORATION, HSINCHU COUNTY (TW)

(21) Appl. No.: 14/269,096

(22) Filed: May 3, 2014

(30) Foreign Application Priority Data
Jan. 29, 2014 (TW) 103103488

(51) Int. Cl. H01L 23/00

(52) U.S. Cl. CPC H01L 24/17; H01L 2924/301; H01L 2924/1434; H01L 2224/1714; H01L 2924/3011

(57) ABSTRACT

A memory comprises a substrate and memory ball pads. The memory ball pads are disposed around the substrate so as to form a ring pattern which show a bilateral symmetry by reflection, wherein the memory ball pads of left-half part of the ring pattern are divided into a first main area, a second main area, a third main area and a fourth main area. The memory ball pads in the first main area are divided into a first sub-region, a second sub-region and a third sub-region, and a plurality of input/output data pins and electricity power pins are disposed in the first sub-region and the third sub-region, wherein the input/output data pins are not adjacent to each other and at least one power voltage pin and at least one ground voltage pin are disposed next to each of the input/output data pins.

### BACKGROUND OF THE INVENTION

1. Field of the Invention

The instant disclosure relates to a memory; in particular, to a layout method of memory ball pads within a memory.

2. Description of Related Art

With the microelectronic technology rapidly developed, peripheral devices of various computer products become advanced, and nowadays consumers use computer products not only for general paper work and surfing the Internet but also for watching videos with high definitions, enjoying the 3D on-line games or dealing with complex application. However, no matter it is the videos with high definitions or kinds of electric documents that are discussed herein, it's known that the file size would be larger if the data becomes more complex. Therefore, the hard disk with high capacity becomes essential for all computer products.

In the prior art, the memory device is generally provided as the inner semiconductor integrated circuit in computers or other electric devices. The memory device comprises various types of memories such as volatile memory and non-volatile memory. The non-volatile memory can store the data even without power supply and comprises NAND flash, NOR flash, ROM, EEPROM, EPROM, PCRAM and other kinds of memories.

DRAM is one memory that has been most developed in the field of semiconductor and is widely used in server stations, laptops, personal computers, pads, host computers and play stations. Generally, the ball layout of DRAM is designed according to the standards set by the Joint Electron Device Engineering Council (JEDEC). However, there's no at least one supply voltage pin and no at least one ground voltage pin disposed besides each input/output data pin. Therefore, there would be a mutual interference that can't be ignored between signals and noises regarding to the circuits layout of the Integrated Circuit (IC).

### SUMMARY OF THE INVENTION

The instant disclosure provides a memory. The memory comprises a substrate and a plurality of memory ball pads. The plurality of memory ball pads are disposed around the substrate so as to form a ring pattern which shows a bilateral symmetry by reflection. The plurality of memory ball pads of left-half part of the ring pattern are divided into a first main area, a second main area, a third main area and a fourth main area. The first main area and the third main area have the same ball layout, and the second main area and the fourth main area have the same ball layout. The plurality of memory ball pads in the first main area are divided into a first sub-region, a second sub-region and a third sub-region, and a plurality of input/output data pins and electricity power pins are disposed in the first sub-region and the third sub-region, wherein the plurality of input/output data pins are not adjacent to each other, and at least one power voltage pin and at least one ground voltage pin are disposed next to each of the plurality of input/output data pins so as to optimize impedances of adjacent signals and reduce noise interferences.

In an embodiment of the instant disclosure, the supply voltage pins and the ground voltage pins are respectively defined as the electricity power pins, and the electricity power pins within the first sub-region are not adjacent to the electricity power pins within the third sub-region.

In an embodiment of the instant disclosure, the second sub-region is disposed between the first sub-region and the third sub-region, and the second sub-region has at least one group of first differential input/output signal pins and the electricity power pins, wherein the supply voltage pin and the ground voltage pin are disposed besides the first differential input/output signal pin.

In an embodiment of the instant disclosure, the memory ball pads within the second main area are divided into a fourth sub-region, a fifth sub-region and a sixth sub-region. The plurality of input/output data pins and electricity power pins are disposed in the fourth sub-region and the sixth sub-region wherein the plurality of input/output data pins are not adjacent to each other, and at least one power voltage pin and at least one ground voltage pin are disposed next to each of the plurality of input/output data pins so as to optimize impedances of adjacent signals and reduce noise interferences.

In an embodiment of the instant disclosure, the fifth sub-region is disposed between the fourth sub-region and the sixth sub-region. Also, the fifth sub-region has at least one group of second differential input/output signal pins and the electricity power pins wherein the supply voltage pin and the ground voltage pin are disposed besides the second differential input/output signal pin.

The instant disclosure also provides a layout method of memory ball pads. The layout method is used in a memory. The memory comprises a substrate and a plurality of memory ball pads. The memory ball pads are disposed around the substrate so as to form a ring pattern which shows a bilateral symmetry by reflection. The layout method of memory ball pads comprises: dividing the plurality of memory ball pads of left-half part of the ring pattern into a first main area, a second main area, a third main area and a fourth main area wherein the first main area and the third main area have the same ball layout and the second main area and the fourth main area have the same ball layout; dividing the memory ball pads within the first main area into a first sub-region, a second sub-region and a third sub-region; disposing a plurality of input/output data pins and electricity power pins in the first sub-region and the third sub-region; and the plurality of input/output data pins are not adjacent to each other and at least one power voltage pin and at least one ground voltage pin are disposed next to each of the plurality of input/output data pins, so as to optimize impedances of adjacent signals and reduce noise interferences.

To sum up, in the memory and the layout method of memory ball pads provided by the instant disclosure, impedances of adjacent signals can be optimized and noise interferences can be reduced via disposing at least one supply voltage pin and at least one ground voltage pin besides each input/output data pin.

For further understanding of the instant disclosure, reference is made to the following detailed description illustrating the embodiments and examples of the instant disclosure. The description is only for illustrating the instant disclosure, not for limiting the scope of the claim.

### BRIEF DESCRIPTION OF THE DRAWINGS

Embodiments are illustrated by way of example and not by way of limitation in the figures of the accompanying drawings, in which like references indicate similar elements and in which:

FIG. 1 shows a schematic diagram of a memory according to an embodiment of the instant disclosure;

FIG. 2 shows a schematic diagram of a first main area according to an embodiment of the instant disclosure; and

FIG. 3 shows a flow chart of a layout method of memory ball pads according to an embodiment of the instant disclosure.

### DETAILED DESCRIPTION OF PREFERRED EMBODIMENTS

The aforementioned illustrations and following detailed descriptions are exemplary for the purpose of further explaining the scope of the instant disclosure. Other objectives and advantages related to the instant disclosure will be illustrated in the subsequent descriptions and appended drawings. In the drawings, the size and relative sizes of layers and regions may be exaggerated for clarity.

It will be understood that, although the terms first, second, third, and the like, may be used herein to describe various elements, components, regions, layers and/or sections, these elements, components, regions, layers and/or sections should not be limited by these terms. These terms are only to distinguish one element, component, region, layer or section from another region, layer or section discussed below could be termed a second element, component, region, layer or section without departing from the teachings of the instant disclosure. As used herein, the term “and/or” includes any and all combinations of one or more of the associated listed items.

[One Embodiment of a Memory]

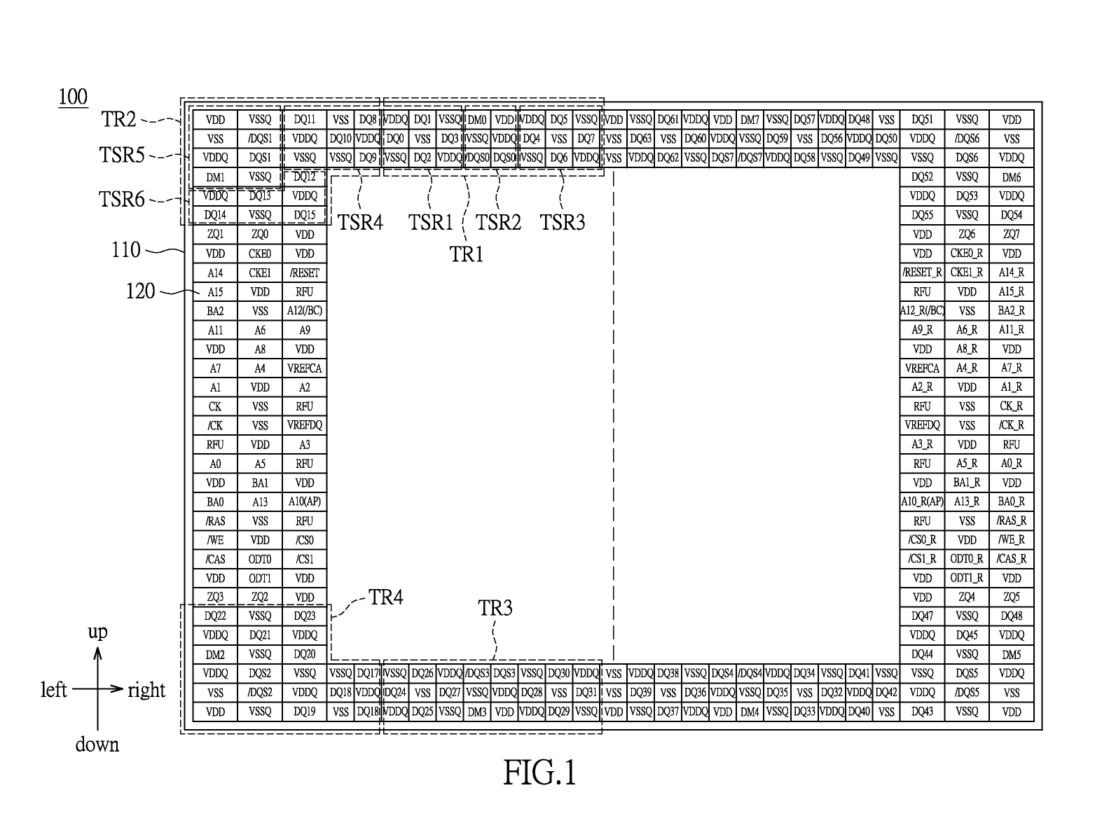

Please refer to FIG. 1, FIG. 1 shows a schematic diagram of a memory according to an embodiment of the instant disclosure. Generally, the layout of memory ball pads regarding to the Dynamic Random Access Memory (DRAM) is regulated by the Joint Electron Device Engineering Council (JEDEC). According to the layout of memory ball pads above, there would not be at least one supply voltage pin and at least one ground voltage pin disposed besides all input/output data pins, such as DQ ball pad so that it could not have a great capacity effect. Therefore, the instant disclosure provides a layout method of memory ball pads such that at least one supply voltage pin and at least one ground voltage pin are disposed besides all input/output data pins, such as the DQ ball pad, so as to have a great capacity effect, further optimize impedances and reduce noise interferences resulted by the supply voltage and the ground voltage as less as possible. Before further instruction, it is clarified that, the layout of the memory 100 provided by the instant disclosure can be applied to the Double-Data-Rate Three Synchronous Dynamic Random Access Memory (DDR3 SDRAM) and the Double-Data-Rate Four (DDR4) latest released on Sep. 26, 2012 by JEDEC responsible for making standards regarding to the memory technology. It is worth mentioning that, the layout of the memory 100 provided by the instant disclosure can be further applied to all kinds of memory storage media. In addition, for a clear instruction and understanding of the instant disclosure, a memory with 64 bits of storage space is taken for an example.

Please continually refer to FIG. 1. In the present embodiment, the memory 100 comprises a substrate 110 and a plurality of memory ball pads 120, and the memory 100 may be a volatile memory. The plurality of memory ball pads 120, such as DQ1, are disposed around the substrate 110 so as to form a ring pattern which shows a bilateral symmetry by reflection so that the layout can be simplified. The plurality of memory ball pads 120 of left-half part of the ring pattern are divided into a first main area TR1, a second main area TR2, a third main area TR3 and a fourth main area TR4. In the present embodiment, the plurality of memory ball pads in the first main area TR1 are divided into a first sub-region TSR1, a second sub-region TSR2 and a third sub-region TSR3. A plurality of input/output data pins, such as DQ0˜DQ7, and electricity power pins, such as VDDQ, VSS and VSSQ, are disposed in the first sub-region TSR1 and the third sub-region TSR3, wherein the plurality of input/output data pins are not adjacent to each other and at least one power voltage pin and at least one ground voltage pin are disposed next to each of the plurality of input/output data pins so as to optimize impedances of adjacent signals and reduce noise interferences. It is worth mentioning that, the supply voltage pins and the ground voltage pins are respectively defined as the electricity power pins, and the electricity power pins within the first sub-region TSR1 are not adjacent to the electricity power pins within the third sub-region TSR3.

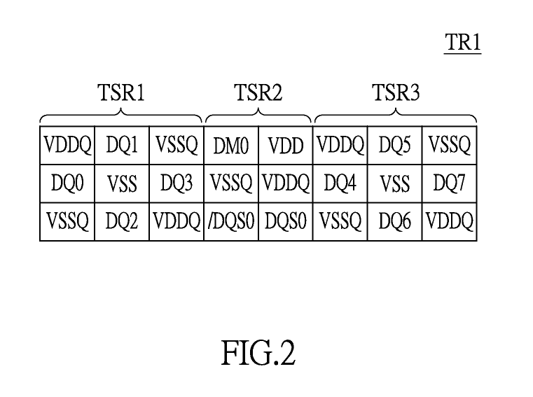

Please also refer to FIG. 2, FIG. 2 shows a schematic diagram of a first main area according to an embodiment of the instant disclosure. Regarding to the first sub-region TSR1 and the third sub-region TSR3, in details, two supply voltage pins (such as VDDQ) and two ground voltage pins, such as (VSS and VSSQ) are disposed besides the input/output data pin (such as DQ0). A supply voltage pin (such as VDDQ) and two ground voltage pins, (such as VSS and VSSQ) are disposed besides the input/output data pin (such as DQ1). A supply voltage pin (such as VDDQ) and two ground voltage pins (such as VSS and VSSQ) are disposed besides the input/output data pin (such as DQ2). A supply voltage pin (such as VDDQ) and three ground voltage pins (such as VSS and VSSQ) are disposed besides the input/output data pin, (such as DQ3). Two supply voltage pins (such as VDDQ) and two ground voltage pins (such as VSS and VSSQ) are disposed besides the input/output data pin (such as DQ4). One supply voltage pin (such as VDDQ) and two ground voltage pins (such as VSS and VSSQ) are disposed besides the input/output data pin (such as DQ5). One supply voltage pin (such as VDDQ) and two ground voltage pins (such as VSS and VSSQ) are disposed besides the input/output data pin (such as DQ6). One supply voltage pin (such as VDDQ) and two ground voltage pins (such as VSS and VSSQ) are disposed besides the input/output data pin (such as DQ7).

Regarding to the second sub-region TSR2 within the first main area TR1, the second sub-region TSR2 are disposed between the first sub-region TSR1 and the third sub-region TSR3, and the second sub-region TSR2 has at least one group of first differential input/output signal pins (such as /DQS0 and DQS0), a plurality of electricity power pins (such as VDD, VDDQ and VSSQ) and an input/output signal pins (such as DM0), wherein the supply voltage pin and the ground voltage pin are disposed besides the first differential input/output signal pins and the first differential input/output signal pin are to transmit or receive differential signals. In the present embodiment, one supply voltage pin (such as VDD) and two ground voltage pin (such as VSSQ) are disposed besides the input/output data pin (such as DM0). In should be noticed that, in the instant disclosure, the first main area TR1 and the third main area TR3 have the same ball layout, and thus the ball layout of the third main area TR3 can be referred to the description regarding to the first main area TR1 and there's no need to go into details.

Please continually refer to FIG. 1, regarding to the second main area TR2, the plurality of memory ball pads 120 within the second main area TR2 are divided into a fourth sub-region TSR4, a fifth sub-region TSR5 and a sixth sub-region TSR6. Also, the plurality of input/output data pins (such as DQ8˜DQ15) and electricity power pins (such as VSS, VSSQ and VDDQ) are disposed in the fourth sub-region TSR4 and the sixth sub-region TSR6 wherein the plurality of input/output data pins are not adjacent to each other and at least one power voltage pin and at least one ground voltage pin are disposed next to each of the plurality of input/output data pins so as to optimize impedances of adjacent signals and reduce noise interferences. In details, two supply voltage pins (such as VDDQ) and one ground voltage pin (such as VSS and VSSQ) are disposed besides the input/output data pin (such as DQ8). One supply voltage pin (such as VDDQ) and two ground voltage pins (such as VSSQ) are disposed besides the input/output data pin (such as DQ9). Two supply voltage pins (such as VDDQ) and two ground voltage pins (such as VSS and VSSQ) are disposed besides the input/output data pin (such as DQ10). One supply voltage pin (such as VDDQ) and two ground voltage pins (such as VSS and VSSQ) are disposed besides the input/output data pin (such as DQ11). One supply voltage pin (such as VDDQ) and two ground voltage pins (such as VSSQ) are disposed besides the input/output data pin (such as DQ12). Two supply voltage pins (such as VDDQ) and two ground voltage pins (such as VSSQ) are disposed besides the input/output data pin (such as DQ13). One supply voltage pin (such as VDDQ) and one ground voltage pin (such as VSSQ) are disposed besides the input/output data pin (such as DQ14). Two supply voltage pins (such as VDD and VDDQ) and one ground voltage pin (such as VSSQ) are disposed besides the input/output data pin (such as DQ15).

Regarding to the fifth sub-region TSR5 within the second main area TR2, the fifth sub-region TSR5 is disposed between the fourth sub-region TSR4 and the sixth sub-region TSR6. The fifth sub-region TSR5 has at least one group of the second differential input/output signal pins (such as /DQS1 and DQS1), a plurality of electricity power pins (such as VDD, VDDQ, VSS and VSSQ) and an input/output signal pin (such as DM1) wherein the supply voltage pin and the ground voltage pin are besides the second differential input/output signal pin, and the second differential input/output signal pin is to transmit or receive signals. In the present embodiment, two supply voltage pins (such as VDDQ) and one ground voltage pin (such as VSSQ) are besides the input/output signal pin (such as DM1). It should be noticed that, in the present instant disclosure, the fourth main area TR4 and the second main area TR2 have the same the ball layout, and thus the ball layout of the fourth main area TR4 can be referred to the description regarding to the second main area TR2 and there's no need to go into details. Moreover, the ball layout of the memory 100 provided by the instant disclosure shows a bilateral symmetry by reflection, and thus the description regarding to the right-half part of the ring pattern of the memory 100 would be substantially the same as the left-half part of the ring pattern of the memory 100 and there's no need to go into details, either.

In the following embodiments, there are only parts different from embodiments in FIG. 1 described, and the omitted parts are indicated to be identical to the embodiments in FIG. 1. In addition, for an easy instruction, similar reference numbers or symbols refer to elements alike.

[Another Embodiment of the Layout Method of the Memory Ball Pad]

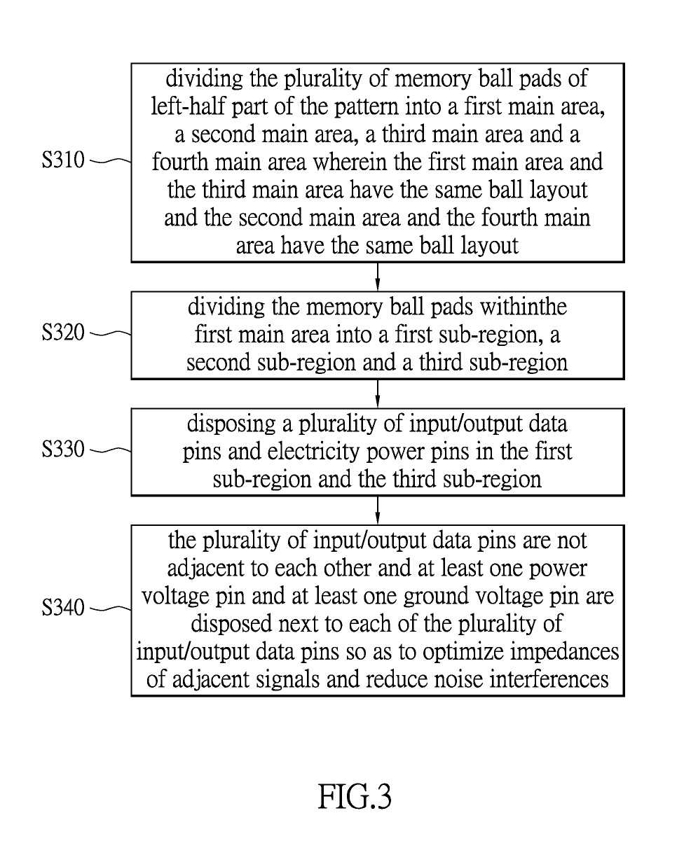

Please refer to FIG. 3, FIG. 3 shows a flow chart of a layout method of memory ball pads according to an embodiment of the instant disclosure. An explanatory sequence of steps in the present embodiment may be embodied with the memory 100 as shown in FIG. 1, and thus please refer to FIG. 1 for an easy understanding. The layout method of the memory ball pad comprises following steps: dividing the plurality of memory ball pads of left-half part of the ring pattern into a first main area, a second main area, a third main area and a fourth main area wherein the first main area and the third main area have the same ball layout and the second main area and the fourth main area have the same ball layout (Step S310); dividing the memory ball pads within the first main area into a first sub-region, a second sub-region and a third sub-region (Step S320); disposing a plurality of input/output data pins and electricity power pins in the first sub-region and the third sub-region (Step S330); and the plurality of input/output data pins are not adjacent to each other and at least one power voltage pin and at least one ground voltage pin are disposed next to each of the plurality of input/output data pins so as to optimize impedances of adjacent signals and reduce noise interferences (Step S340).

Relevant details of the steps of the layout method of the memory ball pad are described in the embodiment of FIG. 1, and thus it is not repeated thereto. It is clarified that, a sequence of steps in FIG. 3 is set for a need to instruct easily, and thus the sequence of the steps is not used as a condition in demonstrating the embodiments of the instant disclosure.

To sum up, in the memory and the layout method of memory ball pads provided by the instant disclosure, impedances of adjacent signals can be optimized and noise interferences can be reduced via disposing at least one supply voltage pin and at least one ground voltage pin besides each input/output data pin.

The descriptions illustrated supra set forth simply the preferred embodiments of the instant disclosure; however, the characteristics of the instant disclosure are by no means restricted thereto. All changes, alternations, or modifications conveniently considered by those skilled in the art are deemed to be encompassed within the scope of the instant disclosure delineated by the following claims.

What is claimed is:

1. A memory, comprising:
a substrate; and
a plurality of memory ball pads, disposed around the substrate so as to form a ring pattern which shows a bilateral symmetry by reflection, wherein the plurality of memory ball pads of left-half part of the ring pattern are divided into a first main area, a second main area, a third main area and a fourth main area, and the first main area and the third main area have the same ball layout and the second main area and the fourth main area have the same ball layout;
wherein the plurality of memory ball pads in the first main area are divided into a first sub-region, a second sub-region and a third sub-region, and a plurality of input/output data pins and electricity power pins are disposed in the first sub-region and the third sub-region wherein the plurality of input/output data pins are not adjacent to each other and at least one power voltage pin and at least one ground voltage pin are disposed next to each of the plurality of input/output data pins so as to optimize impedances of adjacent signals and reduce noise interferences.

2. The memory according to claim 1, wherein the supply voltage pins and the ground voltage pins are respectively defined as the electricity power pins, and the electricity power pins within the first sub-region are not adjacent to the electricity power pins within the third sub-region.

3. The memory according to claim 1, wherein the second sub-region is disposed between the first sub-region and the third sub-region, and the second sub-region has at least one group of first differential input/output signal pins and the electricity power pins, wherein the supply voltage pin and the ground voltage pin are disposed besides the first differential input/output signal pins.

4. The memory according to claim 1, wherein the memory ball pads within the second main area are divided into a fourth sub-region, a fifth sub-region and a sixth sub-region, and the plurality of input/output data pins and electricity power pins are disposed in the fourth sub-region and the sixth sub-region wherein the plurality of input/output data pins are not adjacent to each other and at least one power voltage pin and at least one ground voltage pin are disposed next to each of the plurality of input/output data pins so as to optimize impedances of adjacent signals and reduce noise interferences.

5. The memory according to claim 4, wherein the fifth sub-region is disposed between the fourth sub-region and the sixth sub-region, and the fifth sub-region has at least one group of second differential input/output signal pins and the electricity power pins wherein the supply voltage pin and the ground voltage pin are disposed besides the second differential input/output signal pins.

6. A layout method of memory ball pads, used in a memory, the memory comprising a substrate and a plurality of memory ball pads, the memory ball pads disposed around the substrate so as to form a ring pattern which shows a bilateral symmetry by reflection, the layout method of memory ball pads comprising:
dividing the plurality of memory ball pads of left-half part of the ring pattern into a first main area, a second main area, a third main area and a fourth main area wherein the first main area and the third main area have the same ball layout and the second main area and the fourth main area have the same ball layout;
dividing the memory ball pads within the first main area into a first sub-region, a second sub-region and a third sub-region;
disposing a plurality of input/output data pins and electricity power pins in the first sub-region and the third sub-region; and
the plurality of input/output data pins are not adjacent to each other and at least one power voltage pin and at least one ground voltage pin are disposed next to each of the plurality of input/output data pins so as to optimize impedances of adjacent signals and reduce noise interferences.

7. The layout method of memory ball pads according to claim 6, wherein the supply voltage pins and the ground voltage pins are respectively defined as the electricity power pins, and the electricity power pins within the first sub-region are not adjacent to the electricity power pins within the third sub-region.

8. The layout method of memory ball pads according to claim 6, wherein the second sub-region is disposed between the first sub-region and the third sub-region, and the second sub-region has at least one group of first differential input/output signal pins and the electricity power pins, wherein the supply voltage pin and the ground voltage pin are disposed besides the first differential input/output signal pins.

9. The layout method of memory ball pads according to claim 6, wherein the memory ball pads within the second main area are divided into a fourth sub-region, a fifth sub-region and a sixth sub-region, and the plurality of input/output data pins and electricity power pins are disposed in the fourth sub-region and the sixth sub-region wherein the plurality of input/output data pins are not adjacent to each other and at least one power voltage pin and at least one ground voltage pin are disposed next to each of the plurality of input/output data pins so as to optimize impedances of adjacent signals and reduce noise interferences.

10. The layout method of memory ball pads according to claim 9, wherein the fifth sub-region is disposed between the fourth sub-region and the sixth sub-region, and the fifth sub-region has at least one group of second differential input/output signal pins and the electricity power pins wherein the supply voltage pin and the ground voltage pin are disposed besides the second differential input/output signal pins.
